(19) United States
(12) Patent Application Publication
(10) Pub. No.: US 2023/0413699 A1
(43) Pub. Date: Dec. 21, 2023

(54) SEMICONDUCTOR DEVICE AND METHOD FOR FABRICATING THE SAME

(71) Applicant: SK hynix Inc., Icheon (KR)

(72) Inventors: Hye Jung Choi, Icheon (KR); Jae hyuk Park, Icheon (KR); Seok Man Hong, Icheon (KR)

(21) Appl. No.: 18/061,374

(22) Filed: Dec. 2, 2022

(30) Foreign Application Priority Data
Jun. 17, 2022 (KR) 10-2022-0074052

(51) Int. Cl. H10N 70/00; H10B 63/00

(52) U.S. Cl. CPC H01L 45/149; H01L 45/1253; H01L 45/1641; H01L 45/145; H01L 27/2481; H01L 45/1675

(57) ABSTRACT

A semiconductor device may include: a substrate including a peripheral circuit region and a cell region having a first cell region and a second cell region, the second cell region being farther from the peripheral circuit region than the first cell region; a plurality of memory cells disposed at intersection regions between first conductive lines and second conductive lines, respectively, the memory cells including a first memory cell disposed in the first cell region and a second memory cell disposed in the second cell region, wherein a first electrode layer of the first memory cell and a second electrode layer of the second memory cell include a conductive material, and wherein the first electrode layer further includes a first dopant that increases a resistivity of the conductive material.

### CROSS-REFERENCE TO RELATED APPLICATION

This application claims priority under 35 U.S.C. § 119 to Korean Patent Application No. 10-2022-0074052 filed on Jun. 17, 2022, which is incorporated herein by reference in its entirety.

### BACKGROUND

### 1. Technical Field

This patent document relates to memory circuits or devices and their applications in electronic devices or systems.

### 2. Related Art

Recently, as electronic appliances trend toward miniaturization, low power consumption, high performance, multi-functionality, and so on, semiconductor devices capable of storing information in various electronic appliances such as a computer, a portable communication device, and so on have been demanded in the art, and research has been conducted for the semiconductor devices. Such semiconductor devices include semiconductor storage devices which can store data using a characteristic that they are switched between different resistant states according to an applied voltage or current, for example, an RRAM (resistive random access memory), a PRAM (phase change random access memory), an FRAM (ferroelectric random access memory), an MRAM (magnetic random access memory), an E-fuse, etc.

### SUMMARY

In an embodiment, a semiconductor device may include: a substrate including a peripheral circuit region and a cell region having a first cell region and a second cell region, the second cell region being farther from the peripheral circuit region than the first cell region; a plurality of first conductive lines disposed over the substrate and extending in a first direction; a plurality of second conductive lines disposed over the first conductive lines and extending in a second direction that intersects the first direction; and a plurality of memory cells disposed at intersection regions between the first conductive lines and the second conductive lines, respectively, the memory cells including a first memory cell disposed in the first cell region and a second memory cell disposed in the second cell region, wherein a first electrode layer of the first memory cell and a second electrode layer of the second memory cell include a conductive material, and wherein the first electrode layer further includes a first dopant that increases a resistivity of the conductive material.

In another embodiment, a semiconductor device may include: a substrate including a peripheral circuit region and a cell region having a first cell region and a second cell region, the second cell region being farther from the peripheral circuit region than the first cell region; a plurality of first conductive lines disposed over the substrate and extending in a first direction; a plurality of second conductive lines disposed over the first conductive lines and extending in a second direction that intersects the first direction; a plurality of memory cells respectively disposed at intersection regions between the first conductive lines and the second conductive lines; and a resistance layer disposed between the first conductive line and one or more of the memory cells corresponding to the first conductive line, or between the second conductive line and one or more of the memory cells corresponding to the second conductive line, wherein the resistance layer includes a first resistance layer disposed in the first cell region and a second resistance layer disposed in the second cell region, wherein the first resistance layer and the second resistance layer include a resistance material, and wherein the first resistance layer further includes a dopant that increases a resistivity of the resistance material.

In another embodiment, a method for fabricating a semiconductor device, may include: providing a substrate including a peripheral circuit region and a cell region having a first cell region and a second cell region, the second cell region being farther from the peripheral circuit region than the first cell region; and forming a plurality of first conductive lines extending in a first direction, a plurality of second conductive lines extending in a second direction that intersects the first direction, and a plurality of memory cells disposed at intersections regions between the first conductive lines and the second conductive lines, respectively, over the substrate, wherein the forming of the memory cells includes forming an electrode layer in each of the memory cells, and wherein the forming of the electrode layer includes forming an electrode material layer, doping the electrode material layer in the first cell region with a first dopant for increasing a resistivity of the electrode material layer, and patterning the electrode material layer.

In another embodiment, a method for fabricating a semiconductor device, may include: providing a substrate including a peripheral circuit region and a cell region having a first cell region and a second cell region, the second cell region being farther from the peripheral circuit region than the first cell region; forming a plurality of first conductive lines extending in a first direction, a plurality of second conductive lines extending in a second direction intersecting the first direction, and a plurality of memory cells disposed at intersections regions between the first conductive lines and the second conductive lines, respectively, over the substrate; and forming a resistance layer between the first conductive line and one or more of the memory cells corresponding to the first conductive line, or between the second conductive line and one or more of the memory cells corresponding to the second conductive line, wherein the forming of the resistance layer includes: forming a resistance material layer; and doping the resistance material layer in the first cell region with a dopant that increases a resistivity of the resistance material layer.

### BRIEF DESCRIPTION OF THE DRAWINGS

FIG. 1 is a plan view illustrating a semiconductor device according to an embodiment of the present disclosure.

FIG. 2A is a cross-sectional view taken along a line A-A′ of FIG. 1.

FIG. 2B is a cross-sectional view taken along a line B-B′ of FIG. 1.

FIGS. 3A, 3B, 4A, 4B, 5A, 5B, 6A, 6B, 7A, and 7B are cross-sectional views illustrating an example of a method for fabricating the semiconductor device of FIGS. 1, 2A, and 2B.

FIG. 8 is a plan view illustrating a semiconductor device according to another embodiment of the present disclosure.

FIGS. 9A and 9B are cross-sectional views illustrating a semiconductor device according to another embodiment of the present disclosure, and a method for fabricating the same.

### DETAILED DESCRIPTION

Hereinafter, various embodiments of the disclosure will be described in detail with reference to the accompanying drawings.

The drawings are not necessarily drawn to scale. In some instances, proportions of at least some structures in the drawings may have been exaggerated in order to clearly illustrate certain features of the described embodiments. In presenting a specific example in a drawing or description having two or more layers in a multi-layer structure, the relative positioning relationship of such layers or the sequence of arranging the layers as shown reflects a particular implementation for the described or illustrated example and a different relative positioning relationship or sequence of arranging the layers may be possible. In addition, a described or illustrated example of a multi-layer structure might not reflect all layers present in that particular multilayer structure (e.g., one or more additional layers may be present between two illustrated layers). As a specific example, when a first layer in a described or illustrated multi-layer structure is referred to as being “on” or “over” a second layer or “on” or “over” a substrate, the first layer may be directly formed on the second layer or the substrate but may also represent a structure where one or more other intermediate layers may exist between the first layer and the second layer or the substrate.

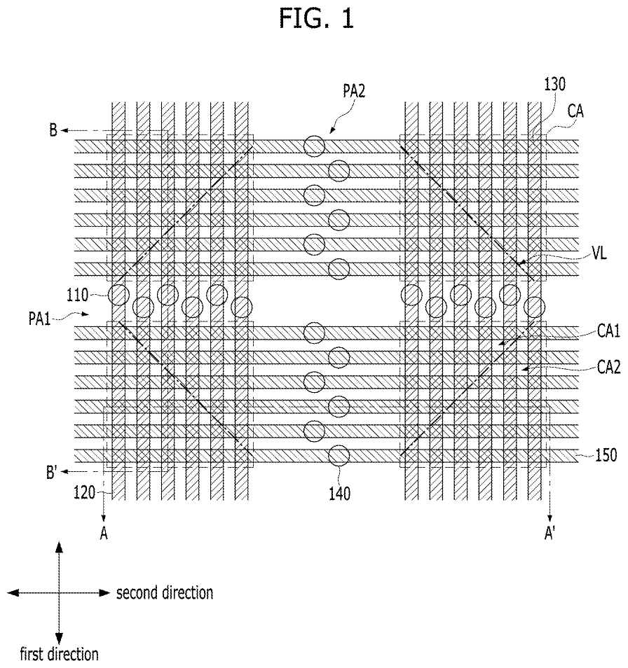

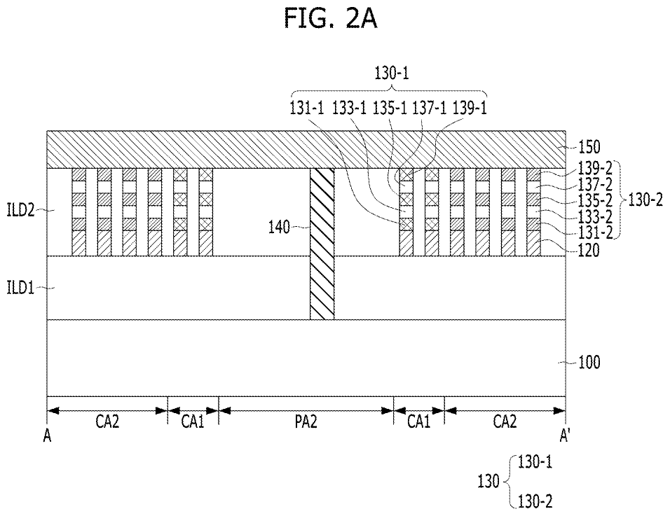

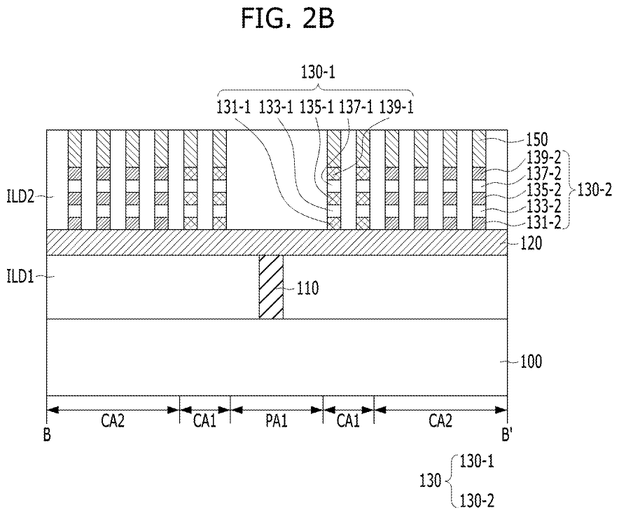

FIG. 1 is a plan view illustrating a semiconductor device according to an embodiment of the present disclosure, FIG. 2A is a cross-sectional view taken along a line A-A′ of FIG. 1, and FIG. 2B is a cross-sectional view taken along a line B-B′ of FIG. 1.

Referring to FIGS. 1, 2A and 2B, the semiconductor device may include a substrate 100, a plurality of first conductive lines 120 disposed over the substrate 100 and extending in a first direction, a plurality of second conductive lines 150 disposed over the first conductive lines 120 and extending in a second direction intersecting the first direction, and a plurality of memory cells 130 disposed between the first conductive lines 120 and the second conductive lines 150 at intersection regions thereof.

The substrate 100 may include a semiconductor material such as silicon. Also, the substrate 100 may include a cell region CA, and peripheral circuit regions PA1 and PA2. The cell region CA may be a region in which the memory cells 130 are disposed, and the peripheral circuit regions PA1 and PA2 may be regions in which driving circuits (not shown) for driving the memory cells 130 are disposed. The memory cells 130 may be disposed over the substrate 100 in the cell region CA, while the driving circuits may be formed in the substrate 100 in the peripheral circuit regions PA1 and PA2.

In the embodiment of FIG. 1, the cell region CA may have a rectangular shape in a plan view, and four cell regions CA may be arranged to be spaced apart from each other in a 2*2 matrix shape along the first direction and the second direction. In addition, in a plan view the peripheral circuit regions PA1 and PA2 may be positioned between the cell regions CA, and may have a cross shape or a grid shape. However, embodiments of the present disclosure are not limited thereto, and the number and arrangement of the cell region CA and the peripheral circuit regions PA1 and PA2 may be variously modified. For convenience of description, a region located between two cell regions CA arranged in the first direction among the peripheral circuit regions PA1 and PA2 will be referred to as a first peripheral circuit region PA1, and a region positioned between two cell regions CA arranged in the second direction among the peripheral circuit regions PA1 and PA2 will be referred to as a second peripheral circuit region PA2.

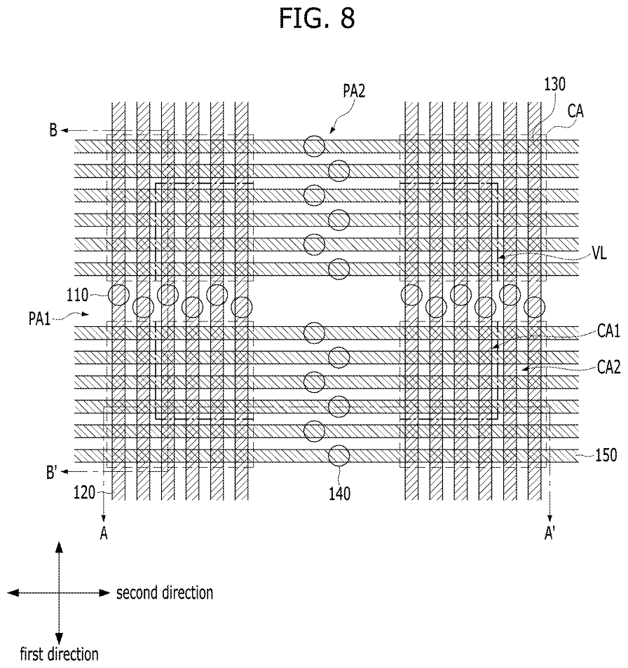

Meanwhile, the cell region CA may include a first cell region CA1 that is relatively adjacent to the peripheral circuit regions PA1 and PA2, and a second cell region CA2 that is relatively far from the peripheral circuit regions PA1 and PA2. Accordingly, an electrical path between the memory cell 130 in the first cell region CA1 and the driving circuit in the peripheral circuit regions PA1 and PA2 may be shorter than an electrical path between the memory cell 130 in the second cell region CA2 and the driving circuit of the peripheral circuit regions PA1 and PA2. In an embodiment, a memory cell 130 in the first cell region CA1 may be spaced apart from the first peripheral circuit region PA1 by a first distance in the first direction via a portion of the first conductive line 120 connected to the memory cell 130, and spaced apart from the second peripheral circuit region PA2 by a second distance in the second direction via a portion of the second conductive line 150 connected to the memory cell 130, such that the sum of the first distance and the second distance may be equal to or less than a given distance (e.g., a predetermined distance). Another memory cell 130 may be disposed in the second cell region CA2 that is farther from the peripheral circuit regions PA1 and PA2 than the first cell region CA1, such that the sum of the first distance and the second distance may exceed the given distance. As an example, a virtual boundary line VL dividing the first cell region CA1 and the second cell region CA2 may extend in a diagonal direction intersecting the first and second directions. However, embodiments of the present disclosure are not limited thereto, and the boundary line VL may be variously modified in consideration of the distance between the memory cell 130 and the peripheral circuit regions PA1 and PA2. For example, as shown in FIG. 8, the shape of the boundary line VL may be modified.

FIG. 8 is a plan view illustrating a semiconductor device according to another embodiment of the present disclosure. In an embodiment, a memory cell 130 in the first cell region CA1 may be spaced apart from the first peripheral circuit region PA1 by a first distance in the first direction via a portion of the first conductive line 120 connected to the memory cell 130, and spaced apart from the second peripheral circuit region PA2 by a second distance in the second direction via a portion of the second conductive line 150 connected to the memory cell 130, such that the first distance may be equal to or less than a first given distance (e.g., a predetermined distance) and the second distance may be equal to or less than a second given distance. Another memory cell 130 may be disposed in the second cell region CA2 that is farther from the peripheral circuit regions PA1 and PA2 than the first cell region CA1, such that the first distance may exceed the first given distance or the second distance may exceed the second given distance.

Referring to FIG. 8, a boundary line VL dividing the first cell region CA1 and the second cell region CA2 may extend in the first direction and the second direction to have a rectangular shape as a whole. By this boundary line VL, the first cell region CA1 may have a virtual rectangular shape having two sides facing the first peripheral circuit region PA1 and the second peripheral circuit region PA2, respectively, and the other two sides. In addition, the second cell region CA2 may have a shape surrounding the other two sides of the first cell region CA1.

Referring to FIGS. 1, 2A, and 2B again, the first conductive line 120 may extend in the first direction to cross the cell region CA and the first peripheral circuit region PA1. The first conductive line 120 may function as a word line or a bit line. The first conductive line 120 may be electrically connected to a part of the substrate 100, for example, a driving circuit formed in the first peripheral circuit region PA1 in the substrate 100, through a first contact plug 110. The first contact plug 110 may be connected to the first conductive line 120 under the first conductive line 120. The first contact plug 110 may be formed to penetrate a first interlayer insulating layer ILD1 between the first conductive line 120 and the substrate 100. The first interlayer insulating layer ILD1 may include at least one of various insulating materials such as silicon oxide, silicon nitride, or a combination thereof. The first conductive line 120 and the first contact plug 110 may include at least one of various conductive materials, for example, a metal such as platinum (Pt), tungsten (W), aluminum (Al), copper (Cu), or tantalum (Ta), a metal nitride such as titanium nitride (TiN) or tantalum nitride (TaN), or a combination thereof. In the embodiment of FIGS. 1, 2A, and 2B, the plurality of first conductive lines 120 and the plurality of first contact plugs 110 may be connected in a one-to-one correspondence. Also, the first contact plugs 110 may be arranged in a zigzag shape along the second direction in a plan view. This may be to secure a gap between the first contact plugs 110 adjacent in the second direction. However, embodiments of the present disclosure are not limited thereto, and the number and arrangement of the first conductive lines 120 and the first contact plugs 110 may be variously modified.

The second conductive line 150 may extend in the second direction to cross the cell region CA and the second peripheral circuit region PA2. When the first conductive line 120 functions as a word line, the second conductive line 150 may function as a bit line. Alternatively, when the first conductive line 120 functions as a bit line, the second conductive line 150 may function as a word line. The second conductive line 150 may be electrically connected to a part of the substrate 100, for example, a driving circuit formed in the second peripheral circuit region PA2 in the substrate 100, through a second contact plug 140. The second contact plug 140 may be connected to the second conductive line 150 under the second conductive line 150. The second contact plug 140 may be formed to penetrate the first interlayer insulating layer ILD1 and a second interlayer insulating layer ILD2 between the second conductive line 150 and the substrate 100. The second interlayer insulating layer ILD2 may include at least one of various insulating materials such as silicon oxide, silicon nitride, or a combination thereof. The second conductive line 150 and the second contact plug 140 may include at least one of various conductive materials, for example, a metal such as platinum (Pt), tungsten (W), aluminum (Al), copper (Cu), or tantalum (Ta), a metal nitride such as titanium nitride (TiN) or tantalum nitride (TaN), or a combination thereof. In the embodiment of FIGS. 1, 2A, and 2B, the plurality of second conductive lines 150 and the plurality of second contact plugs 140 may be connected in a one-to-one correspondence. Also, the second contact plugs 140 may be arranged in a zigzag shape along the first direction in a plan view. This may be to secure a gap between the second contact plugs 140 adjacent in the first direction. However, embodiments of the present disclosure are not limited thereto, and the number and arrangement of the second conductive lines 150 and the second contact plugs 140 may be variously modified.

The memory cells 130 may be arranged in the cell region CA by being positioned at the intersection regions of the first conductive lines 120 and the second conductive lines 150. The memory cell 130 may store different data according to a voltage or current applied to the first conductive line 120 and the second conductive line 150. As an example, the memory cell 130 may include a variable resistance element that stores different data by switching between different resistance states according to a voltage or current applied to the first conductive line 120 and the second conductive line 150.

The memory cell 130 may include a first memory cell 130-1 disposed in the first cell region CA1 and a second memory cell 130-2 disposed in the second cell region CA2. As an example, the first memory cell 130-1 may include a multilayer structure including a first lower electrode layer 131-1, a first selector layer 133-1, a first intermediate electrode layer 135-1, a first variable resistance layer 137-1, and a first upper electrode layer 139-1. Similarly, the second memory cell 130-2 may include a multilayer structure including a second lower electrode layer 131-2, a second selector layer 133-2, a second intermediate electrode layer 135-2, a second variable resistance layer 137-2, and a second upper electrode layer 139-2. In the first memory cell 130-1 and the second memory cell 130-2, layers positioned at substantially the same height and/or level in a specific direction (e.g., a vertical direction) perpendicular to a surface (e.g., an upper surface) of the substrate 100 may correspond to each other. In this way, the layers corresponding to each other may have substantially the same thickness and/or volume as each other. For example, the first lower electrode layer 131-1 and the second lower electrode layer 131-2 may correspond to each other by being positioned at substantially the same height in the vertical direction, and may have substantially the same thickness and/or volume. Similarly, the first selector layer 133-1 and the second selector layer 133-2 may correspond to each other, the first intermediate electrode layer 135-1 and the second intermediate electrode layer 135-2 may correspond to each other, the first variable resistance layer 137-1 and the second variable resistance layer 137-2 may correspond to each other, and the first upper electrode layer 139-1 and the second upper electrode layer 139-2 may correspond to each other.

Here, the first lower electrode layer 131-1 and the second lower electrode layer 131-2 may include a conductive material. The conductive material may include a metal, a metal nitride, carbon, or the like. Furthermore, the first lower electrode layer 131-1, or the second lower electrode layer 131-2, or both may further include a dopant that increases the resistivity of the conductive material. The second lower electrode layer 131-2 may be formed of the conductive material that does not include the dopant. Alternatively, the second lower electrode layer 131-2 may be formed of the conductive material including the dopant, but the concentration and/or content of the dopant in the first lower electrode layer 131-1 may be greater than the concentration and/or content of the dopant in the second lower electrode layer 131-2. Accordingly, a resistivity of a material forming the first lower electrode layer 131-1 may be increased than a resistivity of a material forming the second lower electrode layer 131-2. Since the volume of the first lower electrode layer 131-1 and the volume of the second lower electrode layer 131-2 are substantially the same or at least similar, as a result, a resistance of the first lower electrode layer 131-1 may be increased than a resistance of the second lower electrode layer 131-2.

As an example, the first lower electrode layer 131-1 and the second lower electrode layer 131-2 may include carbon, for example, amorphous carbon. Here, nitrogen may be used as the dopant for increasing a resistance of amorphous carbon. This may be because nitrogen functions to increase the resistance of amorphous carbon by forming sp2 clusters in amorphous carbon. When the second lower electrode layer 131-2 is an amorphous carbon electrode, the first lower electrode layer 131-1 may be an amorphous carbon electrode including nitrogen. Alternatively, when the first lower electrode layer 131-1 and the second lower electrode layer 131-2 each are an amorphous carbon electrode including nitrogen, the nitrogen concentration and/or content of the first lower electrode layer 131-1 may be greater than the nitrogen concentration and/or content of the second lower electrode layer 131-2. The nitrogen content in the first lower electrode layer 131-1 and/or the second lower electrode layer 131-2 may be smaller than that of carbon, which is the main element. For example, the nitrogen content of the first lower electrode layer 131-1 and/or the second lower electrode layer 131-2 may be in a range of 0.1 to 10%.

Similarly, the first intermediate electrode layer 135-1 and the second intermediate electrode layer 135-2 may include a conductive material. The conductive material may include a metal, a metal nitride, carbon, or the like. Furthermore, the first intermediate electrode layer 135-1, or the second intermediate electrode layer 135-2, or both may further include a dopant that increases the resistivity of the conductive material. The second intermediate electrode layer 135-2 may be formed of the conductive material that does not include the dopant. Alternatively, the second intermediate electrode layer 135-2 may be formed of the conductive material to which the dopant is added, but the concentration and/or content of the dopant in the first intermediate electrode layer 135-1 may be greater than the concentration and/or content of the dopant in the second intermediate electrode layer 135-2. Accordingly, a resistivity of a material forming the first intermediate electrode layer 135-1 may be increased than a resistivity of a material forming the second intermediate electrode layer 135-2. As a result, a resistance of the first intermediate electrode layer 135-1 may be increased than a resistance of the second intermediate electrode layer 135-2.

As an example, the first intermediate electrode layer 135-1 and the second intermediate electrode layer 135-2 may include carbon, for example, amorphous carbon, and in this case, nitrogen may be used as the dopant for increasing a resistance of amorphous carbon. When the second intermediate electrode layer 135-2 is an amorphous carbon electrode, the first intermediate electrode layer 135-1 may be an amorphous carbon electrode to which nitrogen is added. Alternatively, when the first intermediate electrode layer 135-1 and the second intermediate electrode layer 135-2 each are an amorphous carbon electrode to which nitrogen is added, the nitrogen concentration and/or content of the first intermediate electrode layer 135-1 may be greater than the nitrogen concentration and/or content of the second intermediate electrode layer 135-2.

Similarly, the first upper electrode layer 139-1 and the second upper electrode layer 139-2 may include a conductive material. The conductive material may include a metal, a metal nitride, carbon, or the like. Furthermore, the first upper electrode layer 139-1, or the second upper electrode layer 139-2, or both may further include a dopant that increases the resistivity of the conductive material. The second upper electrode layer 139-2 may be formed of the conductive material that does not include the dopant. Alternatively, the second upper electrode layer 139-2 may be formed of the conductive material to which the dopant is added, but the concentration and/or content of the dopant in the first upper electrode layer 139-1 may be greater than the concentration and/or content of the dopant in the second upper electrode layer 139-2. Accordingly, a resistivity of a material forming the first upper electrode layer 139-1 may be increased than a resistivity of a material forming the second upper electrode layer 139-2. As a result, a resistance of the first upper electrode layer 139-1 may be increased than a resistance of the second upper electrode layer 139-2.

As an example, the first upper electrode layer 139-1 and the second upper electrode layer 139-2 may include carbon, for example, amorphous carbon, and in this case, nitrogen may be used as the dopant for increasing a resistance of amorphous carbon. When the second upper electrode layer 139-2 is an amorphous carbon electrode, the first upper electrode layer 139-1 may be an amorphous carbon electrode to which nitrogen is added. Alternatively, when the first upper electrode layer 139-1 and the second upper electrode layer 139-2 each are an amorphous carbon electrode to which nitrogen is added, the nitrogen concentration and/or content of the first upper electrode layer 139-1 may be greater than the nitrogen concentration and/or content of the second upper electrode layer 139-2.

In the embodiment described above, a first case where the resistance of the first lower electrode layer 131-1 is greater than the resistance of the second lower electrode layer 131-2, a second case where the resistance of the first intermediate electrode layer 135-1 is greater than the resistance of the second intermediate electrode layer 135-2, and a third case where the resistance of the first upper electrode layer 139-1 is greater than the resistance of the second upper electrode layer 139-2 may be simultaneously implemented. However, embodiments of the present disclosure are not limited thereto. One or more of the first case, the second case, and the third case may be implemented. When only the first case is implemented, the first intermediate electrode layer 135-1 and the second intermediate electrode layer 135-2 may have substantially the same resistance as each other by being formed of the same material, and the first upper electrode layer 139-1 and the second upper electrode layer 139-2 may have substantially the same resistance as each other by being formed of the same material. Similarly, when only the second case is implemented, the first lower electrode layer 131-1 and the second lower electrode layer 131-2 may have substantially the same resistance as each other by being formed of the same material, and the first upper electrode layer 139-1 and the second upper electrode layer 139-2 may have substantially the same resistance as each other by being formed of the same material. Similarly, when only the third case is implemented, the first lower electrode layer 131-1 and the second lower electrode layer 131-2 may have substantially the same resistance as each other by being formed of the same material, and the first intermediate electrode layer 135-1 and the second intermediate electrode layer 135-2 may have substantially the same resistance as each other by being formed of the same material. Alternatively, the first and second cases may be implemented, the first and third cases may be implemented, or the second and third cases may be implemented.

The first and second selector layers 133-1 and 133-2 may be formed of the same material. Each of the first and second selector layers 133-1 and 133-2 may function to prevent or reduce current leakage which may occur between the memory cells 130 sharing the first conductive line 110 or the second conductive line 120. To this end, each of the first and second selector layers 133-1 and 133-2 may have a threshold switching characteristic, that is, a characteristic for blocking or substantially limiting current when a magnitude of an applied voltage is less than a predetermined threshold value and for allowing current to abruptly increase when the magnitude of the applied voltage is above the threshold value. The threshold value may be referred to as a threshold voltage, and each of the first and second selector layers 133-1 and 133-2 may be implemented in a turned-on state or a turned-off state based on the threshold voltage. Each of the first and second selector layers 133-1 and 133-2 may include a diode, an ovonic threshold switching (OTS) material such as a chalcogenide-based material, a mixed ionic electronic conducting (MIEC) material such as a metal-containing chalcogenide-based material, a metal insulator transition (MIT) material such as NbO₂, VO₂, or the like, or a tunneling insulating layer having a relatively wide band gap, such as SiO₂, Al₂O₃, or the like.

The first and second variable resistance layers 137-1 and 137-2 may be formed of the same material. Each of the first and second variable resistance layers 137-1 and 137-2 may be a part that stores data in the memory cell 130. To this end, each of the first and second variable resistance layers 137-1 and 137-2 may have a variable resistance characteristic that switches between different resistance states according to an applied voltage. Each of the first and second variable resistance layers 137-1 and 137-2 may have a single-layer structure or a multi-layer structure including at least one of materials used for an RRAM, a PRAM, an MRAM, an FRAM, or the like, that is, a metal oxide such as a perovskite-based oxide or a transition metal oxide, a phase change material such as a chalcogenide-based material, a ferromagnetic material, a ferroelectric material, or the like.

However, the structure of the memory cell 130 may be variously modified. As an example, in each of the first and second memory cells 130-1 and 130-2, one or more of the first and second lower electrode layers 131-1 and 131-2, the first and second intermediate electrode layers 135-1 and 135-2, the first and second upper electrode layers 139-1 and 139-2, and the first and second selector layers 133-1 and 133-2 may be omitted. Alternatively, as an example, the upper and lower positions of the first and second variable resistance layers 137-1 and 137-2 and the first and second selector layers 133-1 and 133-2 may be reversed with each other. Alternatively, as an example, the memory cell 130 may further include one or more layers (not shown) to improve characteristics or fabricating processes of the memory cell 130. Alternatively, as an example, the memory cell 130 may have a structure in which a layer simultaneously performing a function as a memory layer and a function as a selector layer is interposed between a lower electrode layer and an upper electrode layer, and thus, the memory cell 130 may function as a self-selecting memory cell. That is, the memory cell 130 may have a structure in which a lower electrode layer, a layer having a variable resistance characteristic and a selector characteristic at the same time, and an upper electrode layer are stacked. At this time, as long as the above-described correspondence between the layers forming the first memory cell 130-1 and the second memory cell 130-2 is maintained, the stacking order of the layers may be changed, at least one of the layers may be omitted, and one or more layers may be added. For example, if the first lower electrode layer 131-1 is omitted, the second lower electrode layer 131-2 may also be omitted.

The effect of the semiconductor device described above will be described in comparison with a comparative example as follows.

In the semiconductor device of the comparative example, the memory cells may have the same structure regardless of the distance between the memory cell and the peripheral circuit region. In this comparative example, it may be necessary to supply a large amount of current through the upper and lower conductive lines in order to drive the memory cell relatively far from the peripheral circuit region. When a large amount of current is supplied through the upper and lower conductive lines, an excessive overshooting current or a spike current may flow through the memory cell relatively close to the peripheral circuit region, thereby causing an operation failure of the memory cell.

In contrast, according to embodiments of the present disclosure, when the resistance of one or more of the first lower electrode layer 131-1, the first intermediate electrode layer 135-1, and the first upper electrode layer 139-1 of the first memory cell 130-1 in the first cell region CA1 may be increased compared to the resistance of one or more of the second lower electrode layer 131-2, the second intermediate electrode layer 135-2, and the second upper electrode layers 139-2 of the second memory cell 130-2 in the second cell region CA2, the issue of the comparative example may be addressed. Specifically, since voltage/current transfer into the second selector layer 133-2 and/or the second variable resistance layer 137-2 of the second memory cell 130-2 is performed through the second lower electrode layer 131-2, the second intermediate electrode layer 135-2, and/or the second upper electrode layer 139-2 that have a relatively low-resistance, it may be facilitated to drive the second memory cell 130-2. In addition, since voltage/current transfer into the first selector layer 133-1 and/or the first variable resistance layer 137-1 of the first memory cell 130-1 is performed through the first lower electrode layer 131-1, the first intermediate electrode layer 135-1, and/or the first upper electrode layer 139-1 that have a relatively high-resistance, it may be possible to prevent excessive current from flowing through the first memory cell 130-1. Accordingly, an excessive overshooting current or a spike current may not flow through the first memory cell 130-1 that is disposed relatively proximate to the peripheral circuit region, thereby ensuring the reliability of an operation of the memory cell 130-1.

Furthermore, as will be described later in a fabricating method according to an embodiment of the present disclosure, the resistances of the first lower electrode layer 131-1, the first intermediate electrode layer 135-1, the first upper electrode layer 139-1, the second lower electrode layer 131-2, the second intermediate electrode layer 135-2, and the second upper electrode layer 139-2 may be adjusted by performing a doping process, which can be implemented relatively simply in the fabricating method.

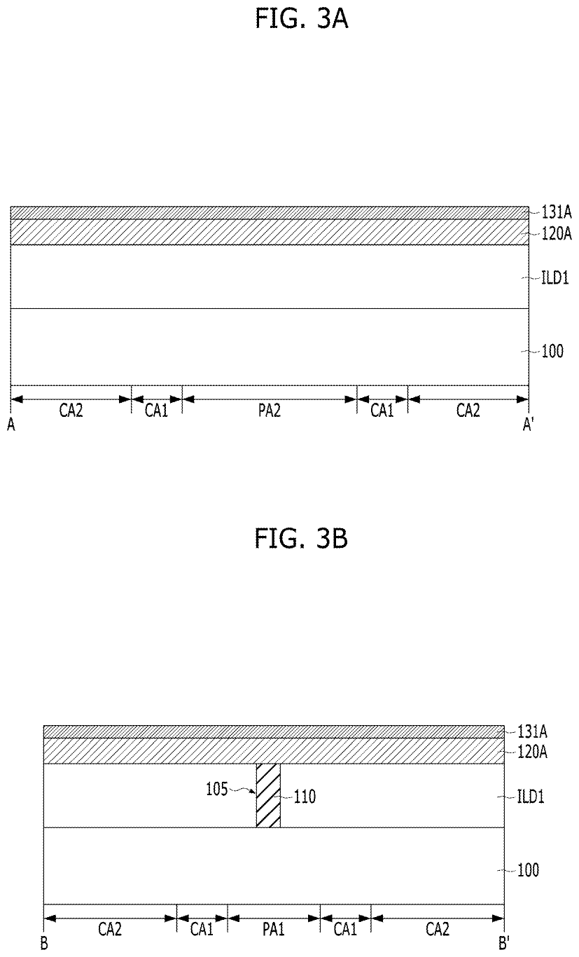

FIGS. 3A to 7B are cross-sectional views illustrating an example of a method for fabricating the semiconductor device of FIGS. 1, 2A, and 2B. FIGS. 3A, 4A, 5A, 6A, and 7A are shown based on a cross-section taken along a line A-A′ of FIG. 1, and FIGS. 3B, 4B, 5B, 6B, and 7B are shown based on a cross-section taken along a line B-B′ of FIG. 1.

Referring to FIGS. 3A and 3B, a substrate 100 including a first cell region CA1, a second cell region CA2, a first peripheral circuit region PA1, and a second peripheral circuit region PA2 may be provided, and a first interlayer insulating layer ILD1 may be formed over the substrate 100.

Next, a first contact hole 105 exposing a portion of the substrate 100 may be formed by selectively etching the first interlayer insulating layer ILD1 of the first peripheral circuit region PA1, and then, a first contact plug 110 may be formed by depositing a conductive material having a thickness sufficient to fill the first contact hole 105, and performing a planarization process, for example, chemical mechanical polishing (CMP) until the upper surface of the first interlayer insulating layer ILD1 is exposed.

Next, a first conductive material layer 120A for forming a first conductive line and a lower electrode material layer 131A for forming first and second lower electrode layers may be formed over the first interlayer insulating layer ILD1 in which the first contact plug 110 is formed. The lower electrode material layer 131A may include amorphous carbon. For example, the lower electrode material layer 131A may include an amorphous carbon layer or an amorphous carbon layer containing nitrogen. In addition, the first conductive material layer 120A and the lower electrode material layer 131A may be formed by at least one of various deposition methods such as physical vapor deposition (PVD), chemical vapor deposition (CVD), or atomic layer deposition (ALD).

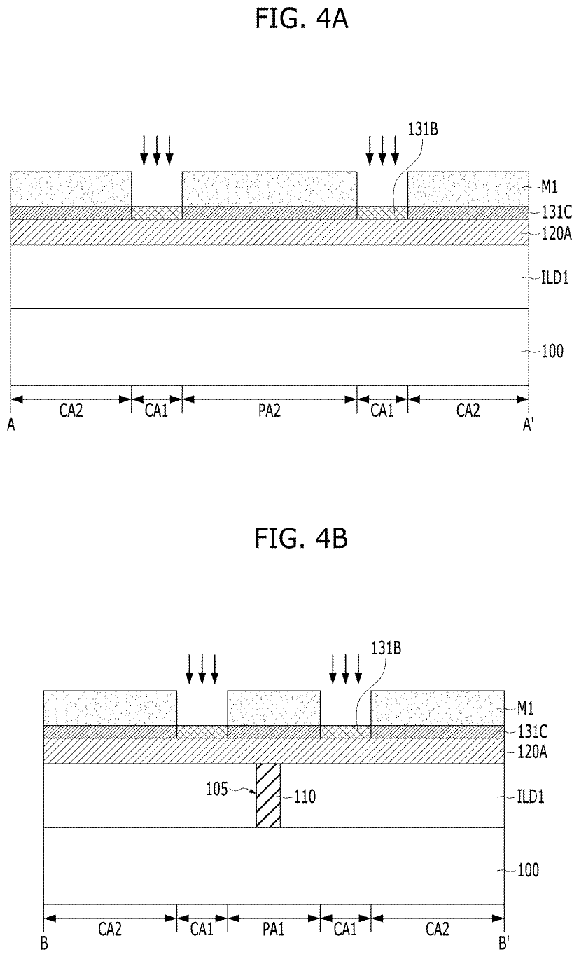

Referring to FIGS. 4A and 4B, after a mask pattern M1 is formed over the resultant structure of FIGS. 3A and 3B to expose the first cell region CA1 and cover the remaining regions, that is, the second cell region CA2 and the peripheral circuit regions PA1 and PA2, a dopant that increases the resistivity of the lower electrode material layer 131A may be doped into a portion of the lower electrode material layer 131A exposed by the mask pattern M1. When the lower electrode material layer 131A includes amorphous carbon, the dopant may include nitrogen. In addition, for example, doping of the dopant may be performed by ion implantation.

As a result of this process, the lower electrode material layer 131A may be changed to a first lower electrode material layer 131B of the first cell region CA1, and a second lower electrode material layer 131C of the second cell region CA2 and the peripheral circuit regions PA1 and PA2. The first lower electrode material layer 131B may be a material in which the dopant is added to the lower electrode material layer 131A, and may have an increased resistivity than the lower electrode material layer 131A. When the lower electrode material layer 131A includes an amorphous carbon layer, the first lower electrode material layer 131B may include an amorphous carbon layer containing nitrogen. Alternatively, when the lower electrode material layer 131A includes an amorphous carbon layer containing nitrogen, the first lower electrode material layer 131B may include an amorphous carbon layer containing a higher concentration and/or content of nitrogen than the lower electrode material layer 131A. The second lower electrode material layer 131C may be substantially the same as the lower electrode material layer 131A.

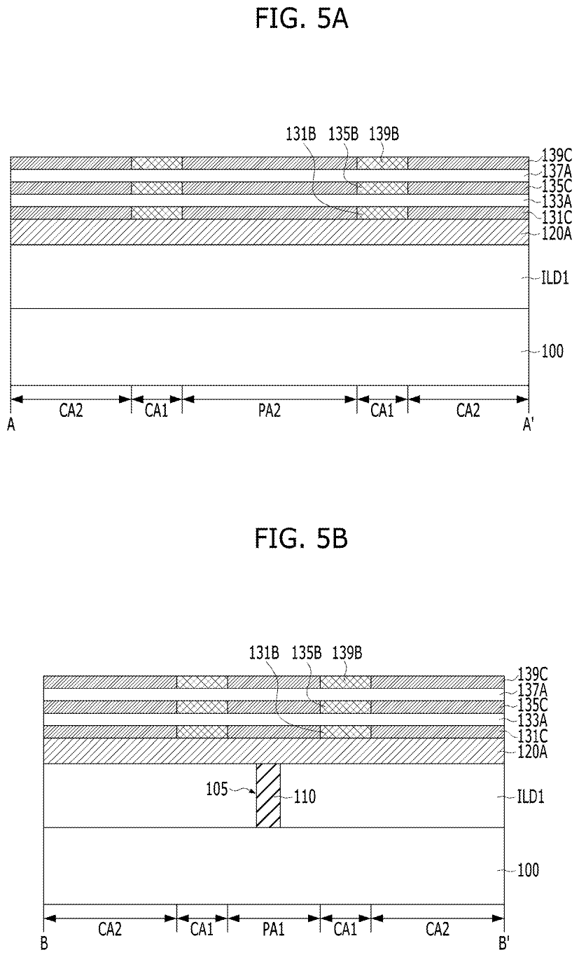

Referring to FIGS. 5A and 5B, after removing the mask pattern M1, a selector material layer 133A for forming first and second selector layers may be formed over the first lower electrode material layer 131B and the second lower electrode material layer 131C.

Subsequently, a first intermediate electrode material layer 135B and a second intermediate electrode material layer 135C may be formed over the selector material layer 133A. The forming process of the first intermediate electrode material layer 135B and the second intermediate electrode material layer 135C may be substantially the same as the above-described forming process of the first lower electrode material layer 131B and the second lower electrode material layer 131C. That is, after an intermediate electrode material layer (not shown) is formed over the selector material layer 133A, the intermediate electrode material layer of the first cell region CA1 may be selectively doped with a dopant that increases a resistivity of the intermediate electrode material layer, thereby forming the first intermediate electrode material layer 1358 and the second intermediate electrode material layer 135C. Specifically, a portion of the intermediate electrode material layer in the first cell region CA1 may be selectively doped with such a dopant to form the first intermediate electrode material layer 1358.

Subsequently, a variable resistance material layer 137A for forming first and second variable resistance layers may be formed over the first intermediate electrode material layer 1358 and the second intermediate electrode material layer 135C.

Subsequently, a first upper electrode material layer 1398 and a second upper electrode material layer 139C may be formed over the variable resistance material layer 137A. The forming process of the first upper electrode material layer 1398 and the second upper electrode material layer 139C may be substantially the same as the above-described forming process of the first lower electrode material layer 1318 and the second lower electrode material layer 131C. That is, after forming an upper electrode material layer (not shown) over the variable resistance material layer 137A, the upper electrode material layer of the first cell region CA1 may be selectively doped with a dopant that increases a resistivity of the upper electrode material layer, thereby forming the first upper electrode material layer 139B and the second upper electrode material layer 139C.

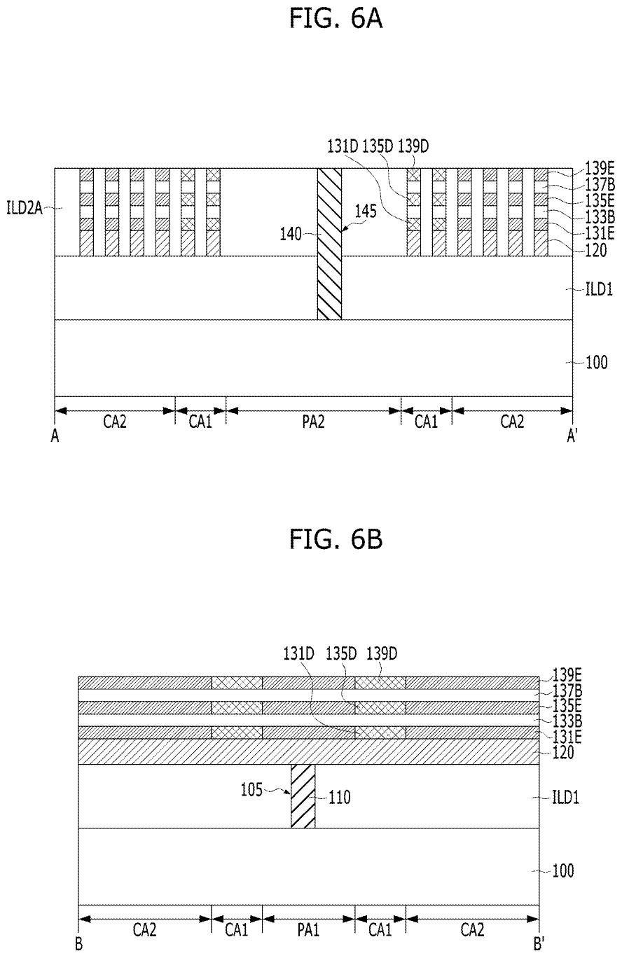

Referring to FIGS. 6A and 6B, the first conductive material layer 120A, the first and second lower electrode material layers 131B and 131C, the selector material layer 133A, the first and second intermediate electrode material layers 135B and 135C, the variable resistance material layer 137A, and the first and second upper electrode material layers 139B and 139C may be etched using a line-shaped mask pattern (not shown) extending in the first direction as an etch barrier. As a result, a first conductive line 120 and a stacked structure of first and second lower electrode material patterns 131D and 131E, a selector material pattern 133B, first and second intermediate electrode material patterns 135D and 135E, a variable resistance material pattern 137B, and first and second upper electrode material patterns 139D and 139E may be formed. The stacked structure may have a line shape overlapping the first conductive line 120 over the first conductive line 120.

Subsequently, an initial second interlayer insulating layer ILD2A may be formed to fill the space between the plurality of first conductive lines 120 and between the stacked structures. The initial second interlayer insulating layer ILD2A may be formed by depositing an insulating material having a thickness sufficient to cover the first conductive line 120 and the stacked structure, and performing a planarization process until the upper surface of the stacked structure is exposed.

Subsequently, a second contact hole 145 exposing a portion of the substrate 100 may be formed by selectively etching the initial second interlayer insulating layer ILD2A and the first interlayer insulating layer ILD1 of the second peripheral circuit region PA2, and then, a second contact plug 140 filled in the second contact hole 145 may be formed.

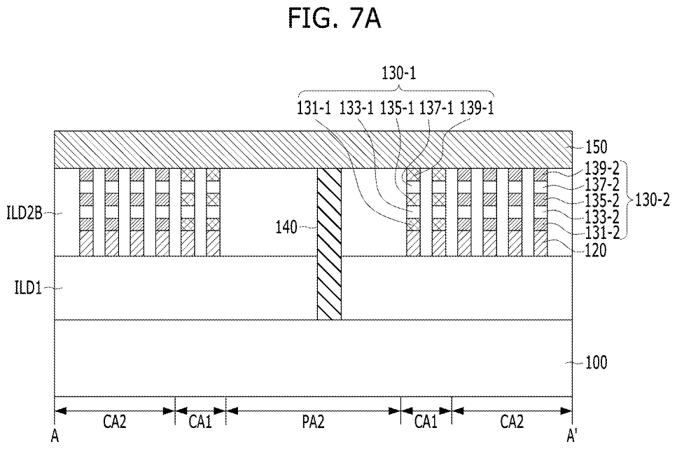

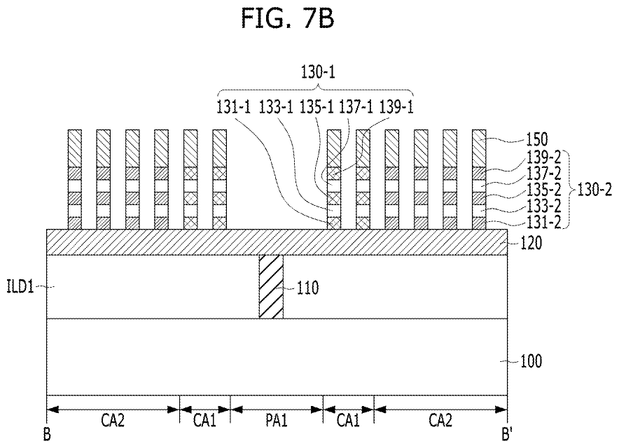

Referring to FIGS. 7A and 7B, a second conductive line 150 may be formed over the resultant structure of FIGS. 6A and 6B. The second conductive line 150 may be formed by forming a second conductive material layer (not shown) over the resultant structure of FIGS. 6A and 6B, and etching the second conductive material layer using a line-shaped mask pattern (not shown) extending in the second direction.

Subsequently, first and second memory cells 130-1 and 130-2 may be formed by etching the stacked structure of the first and second lower electrode material patterns 131D and 131E, the selector material pattern 133B, the first and second intermediate electrode material patterns 135D and 135E, the variable resistance material pattern 137B, and the first and second upper electrode material patterns 139D and 139E, exposed by the second conductive line 150. This etching process may be performed using a mask pattern for forming the second conductive line 150 as an etching barrier. Each of the first and second memory cells 130-1 and 130-2 may overlap an intersection region of the first conductive line 120 and the second conductive line 150 between the first conductive line 120 and the second conductive line 150, and may have a rectangular pillar shape that has both sidewalls aligned with both sidewalls of the first conductive line 120 in the second direction and both sidewalls aligned with both sidewalls of the second conductive line 150 in the first direction. The etched first lower electrode material pattern 131D, the etched selector material pattern 133B of the first cell region CA1, the etched first intermediate electrode material pattern 135D, the etched variable resistance material pattern 137B of the first cell region CA1, and the etched first upper electrode material pattern 139D may form a first lower electrode layer 131-1, a first selector layer 133-1, a first intermediate electrode layer 135-1, a first variable resistance layer 137-1, and a first upper electrode layer 139-1, thereby forming the first memory cell 130-1 including them. In addition, the etched second lower electrode material pattern 131E, the etched selector material pattern 133B of the second cell region CA2, the etched second intermediate electrode material pattern 135E, the etched variable resistance material pattern 137B of the second cell region CA2, and the etched second upper electrode material pattern 139E may form a second lower electrode layer 131-2, a second selector layer 133-2, a second intermediate electrode layer 135-2, a second variable resistance layer 137-2, and a second upper electrode layer 139E, thereby forming the second memory cell 130-2 including them. In this etching process, the initial second interlayer insulating layer ILD2A may be etched together to be transformed into an intermediate second interlayer insulating layer ILD2B.

Subsequently, although not shown, a space between the second conductive lines 150, a space between the first and second memory cells 130-1 and 130-2, and a space between the intermediate second interlayer insulating layers ILD2B may be filled with an insulating material (not shown), and thus, a semiconductor device substantially identical to that described in FIGS. 2A and 2B may be obtained. The intermediate second interlayer insulating layer ILD2B, and the insulating material (not shown) may form the second interlayer insulating layer ILD2 of FIGS. 2A and 2B.

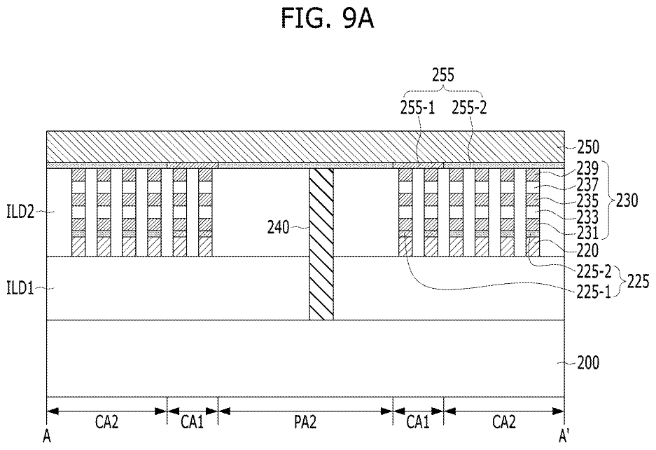

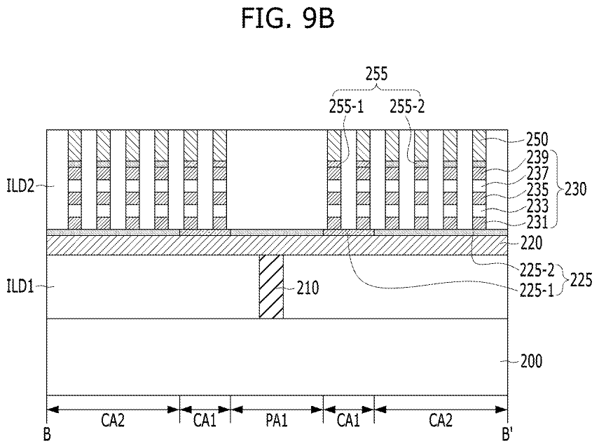

FIGS. 9A and 9B are cross-sectional views illustrating a semiconductor device according to another embodiment of the present disclosure, and a method for fabricating the same. FIG. 9A may substantially correspond to a cross-section taken along a line A-A′ of FIG. 1, and FIG. 9B may substantially correspond to a cross-section taken along a line B-B′ of FIG. 1. Differences from the above-described embodiment will be mainly described.

Referring to FIGS. 9A and 9B, the semiconductor device may include a substrate 200, first conductive lines 220 disposed over the substrate 200 and extending in a first direction, second conductive lines 250 disposed over the first conductive lines 220 and extending in a second direction intersecting the first direction, and memory cells 230 positioned between the first conductive lines 220 and the second conductive lines 250 at intersection regions thereof.

The first conductive line 220 may be connected to a portion of the substrate 200, for example, a driving circuit formed in the first peripheral circuit region PA1 in the substrate 200, through a first contact plug 210. The first contact plug 210 may be disposed in the first peripheral circuit region PA1, and may be connected to the first conductive line 220 under the first conductive line 220. The second conductive line 250 may be connected to a portion of the substrate 200, for example, a driving circuit formed in the second peripheral circuit region PA2 in the substrate 200, through a second contact plug 240. The second contact plug 240 may be disposed in the second peripheral circuit region PA2, and may be connected to the second conductive line 250 under the second conductive line 250. The first conductive line 220 and the second conductive line 250 may include a conductive material having a relatively low resistance, such as a metal or a metal nitride.

The memory cell 230 may include an element capable of storing different data according to a voltage or current applied to the first conductive line 220 and the second conductive line 250, for example, a variable resistance element. As an example, the memory cell 230 may include a multilayer structure including a lower electrode layer 231, a selector layer 233, an intermediate electrode layer 235, a variable resistance layer 237, and an upper electrode layer 239. In the embodiment of FIGS. 9A and 9B, the memory cell 230 may have substantially the same structure in the first cell region CA1 and the second cell region CA2. That is, the lower electrode layer 231, the intermediate electrode layer 235, and the upper electrode layer 239 may have various conductive materials such as a metal, a metal nitride, carbon, or the like, regardless of whether the memory cell 230 is disposed in the first cell region CA1 or the second cell region CA2.

A first resistance layer (e.g., a lower resistance layer) 225 may be interposed between the first conductive line 220 and the memory cell 230. For example, the lower resistance layer 225 may be interposed between the first conductive line 220 and corresponding one or more memory cells 230 coupled to the lower resistance layer 225. The lower resistance layer 225 may include a resistance material having a resistivity greater than that of a material forming the first conductive line 220, and a current may flow through the lower resistance layer 225 under a driving voltage of the memory cell 230. For example, the resistance material may include tungsten silicon nitride (WSiN). For smooth transmission of current/voltage through the first conductive line 220, the thickness of the lower resistance layer 225 may be smaller than the thickness of the first conductive line 220. Also, the lower resistance layer 225 may have substantially the same line shape as the first conductive line 220 while overlapping the first conductive line 220 in a plan view.

The lower resistance layer 225 may include a first lower resistance layer 225-1 in the first cell region CA1 and a second lower resistance layer 225-2 in the second cell region CA2 and the peripheral circuit regions PA1 and PA2. When the second lower resistance layer 225-2 includes a predetermined resistance material, the first lower resistance layer 225-1 may further include a dopant that increases a resistivity of the resistance material. For example, when the second lower resistance layer 225-2 includes tungsten silicon nitride, the first lower resistance layer 225-1 may include tungsten silicon nitride containing a higher concentration of nitrogen, or a higher concentration of silicon, or both, compared to the second lower resistance layer 225-2. The lower resistance layer 225 may be formed by forming a tungsten silicon nitride layer using various deposition methods over a conductive layer for forming the first conductive line 220, and selectively doping one or both of nitrogen and silicon into the tungsten silicon nitride layer of the first cell region CA1, similar to that described in the embodiment of the above-described fabricating method. When the tungsten silicon nitride layer is further doped with nitrogen and/or silicon, a WN-Si3N4 bond may be formed, and resistance thereof may increase. Since the first lower resistance layer 225-1 may include tungsten silicon nitride containing a higher concentration of nitrogen, or a higher concentration of silicon, or both, than the second lower resistance layer 225-2, the first lower resistance layer 225-1 may have resistivity higher than that of the second lower resistance layer 225-2.

Similarly, a second resistance layer (e.g., an upper resistance layer) 255 may be interposed between the second conductive line 250 and the memory cell 230. The upper resistance layer 255 may include a resistance material having a resistivity greater than that of a material forming the second conductive line 250, and a current may flow through the upper resistance layer 255 under the driving voltage of the memory cell 230. For example, the resistance material may include tungsten silicon nitride (WSiN). For smooth transmission of current/voltage through the second conductive line 250, the thickness of the upper resistance layer 255 may be smaller than the thickness of the second conductive line 250. Also, the upper resistance layer 255 may have substantially the same line shape as the second conductive line 250 while overlapping the second conductive line 250 in a plan view.

The upper resistance layer 255 may include a first upper resistance layer 255-1 in the first cell region CA1 and a second upper resistance layer 255-2 in the second cell region CA2. When the second upper resistance layer 255-2 includes a predetermined resistance material, the first upper resistance layer 255-1 may further include a dopant that increases a resistivity of the resistance material. For example, when the second upper resistance layer 255-2 includes tungsten silicon nitride, the first upper resistance layer 255-1 may include tungsten silicon nitride containing a higher concentration of nitrogen, or a higher concentration of silicon, or both, compared to the second upper resistance layer 255-2. The upper resistance layer 255 may be formed by forming a tungsten silicon nitride layer using various deposition methods over an underlying structure, and selectively doping one or both of nitrogen and silicon into the tungsten silicon nitride layer of the first cell region CA1, similar to that described in the embodiment of the above-described fabricating method.

In the embodiment of FIGS. 9A and 9B, except that the lower resistance layer 225 and the upper resistance layer 255 are additionally formed, the lower resistance layer 225 is patterned together with the first conductive line 220, and the upper resistance layer 255 is patterned together with the second conductive line 250, the manufacturing method thereof may be substantially the same as in the above-described embodiment, and thus a detailed description thereof will be omitted for the interest of brevity.

In the embodiment of FIGS. 9A and 9B, a fourth case where the lower resistance layer 225 includes the second lower resistance layer 225-2 and the first lower resistance layer 225-1 having a higher resistance than that of the second lower resistance layer 225-2, and a fifth case where the upper resistance layer 255 includes the second upper resistance layer 255-2 and the first upper resistance layer 255-1 having a higher resistance than that of the second upper resistance layer 255-2, may be simultaneously implemented. But embodiments of the present disclosure are not limited thereto. One or both of the fourth case and the fifth case may be implemented. When only the fourth case is implemented, the upper resistance layer 255 may include a resistance material having a uniform resistance in the first cell region CA1 and the second cell region CA2, or the upper resistance layer 255 itself may be omitted. When only the fifth case is implemented, the lower resistance layer 225 may include a resistance material having a uniform resistance in the first cell region CA1 and the second cell region CA2, or the lower resistance layer 225 may be omitted.

The semiconductor devices according to the above-described embodiments of the present disclosure may address the issues of the above-described comparative example. Specifically, by further increasing the resistance of the lower resistance layer 225 and/or the upper resistance layer 255 in the first cell region CA1 compared to the second cell region CA2, it may be possible to facilitate the driving of the memory cell 230 of the second cell region CA2 while preventing excessive current from flowing through the memory cell 230 of the first cell region CA1.

Furthermore, the resistance adjustment of the lower resistance layer 225 and/or the upper resistance layer 255 is possible by performing a doping process, which can be implemented relatively simply in the fabricating method.

Meanwhile, the embodiments described above may be combined with each other. That is, one or more of the first to third cases described in the embodiment of FIGS. 2A and 2B and one or both of the fourth and fifth cases described in the embodiment of FIGS. 9A and 9B may be combined. For example, when the first case and the fourth case are combined, the lower electrode layer of the memory cell of the first cell region may have a higher resistance than the lower electrode layer of the memory cell of the second cell region, and a resistance of the first lower resistance layer of the first cell region may be greater than a resistance of the second lower resistance layer of the second cell region. Various cases may be combinable in a similar manner. In any case, by preventing an excessive current from flowing through the memory cell in the first cell region, it may be possible to prevent or reduce the occurrence of an operation failure of the memory cell due to the overshooting current or the like.

According to the above embodiments of the present disclosure, it may be possible to improve the operating characteristics of the semiconductor device and simplify fabricating processes thereof.

Although various embodiments have been described for illustrative purposes, it will be apparent to those skilled in the art that various changes and modifications may be possible.

What is claimed is:

1. A semiconductor device comprising:
a substrate including a peripheral circuit region and a cell region having a first cell region and a second cell region, the second cell region being farther from the peripheral circuit region than the first cell region;
a plurality of first conductive lines disposed over the substrate and extending in a first direction;
a plurality of second conductive lines disposed over the first conductive lines and extending in a second direction that intersects the first direction; and
a plurality of memory cells disposed at intersection regions between the first conductive lines and the second conductive lines, respectively, the memory cells including a first memory cell disposed in the first cell region and a second memory cell disposed in the second cell region,
wherein a first electrode layer of the first memory cell and a second electrode layer of the second memory cell include a conductive material, and
wherein the first electrode layer further includes a first dopant that increases a resistivity of the conductive material.

2. The semiconductor device according to claim 1, wherein the second electrode layer further includes the first dopant, and a content of the first dopant in the first electrode layer is greater than a content of the first dopant in the second electrode layer.

3. The semiconductor device according to claim 2, wherein the conductive material includes amorphous carbon, and the first dopant includes nitrogen.

4. The semiconductor device according to claim 1, wherein the conductive material includes amorphous carbon, and the first dopant includes nitrogen.

5. The semiconductor device according to claim 1, wherein the first electrode layer and the second electrode layer are positioned at the same level in a direction perpendicular to a surface of the substrate and have the same volume.

6. The semiconductor device according to claim 1, wherein the first memory cell includes a variable resistance layer,
wherein the first electrode layer of the first memory cell is positioned over or under the variable resistance layer, and
wherein the second electrode layer of the second memory cell is positioned at the same level as the first electrode layer in a direction perpendicular to a surface of the substrate.

7. The semiconductor device according to claim 1, wherein the first memory cell includes a selector layer and a variable resistance layer stacked in a vertical direction perpendicular to a surface of the substrate,
wherein the first electrode layer of the first memory cell is positioned over the variable resistance layer, or under the selector layer, or between the variable resistance layer and the selector layer, and
wherein the second electrode layer of the second memory cell is positioned at the same level as the first electrode layer in the vertical direction.

8. The semiconductor device according to claim 1, wherein the first memory cell includes a variable resistance layer and a selector layer stacked in a vertical direction perpendicular to a surface of the substrate,
wherein the first electrode layer of the first memory cell is positioned under the variable resistance layer, or over the selector layer, or between the variable resistance layer and the selector layer, and
wherein the second electrode layer of the second memory cell is positioned at the same level as the first electrode layer in the vertical direction.

9. The semiconductor device according to claim 1, further comprising:
a resistance layer disposed between the first conductive line and one or more of the memory cells corresponding to the first conductive line, or between the second conductive line and one or more of the memory cells corresponding to the second conductive line.

10. The semiconductor device according to claim 9, wherein the resistance layer includes a first resistance layer in the first cell region and a second resistance layer in the second cell region,
wherein the first resistance layer and the second resistance layer include a resistance material, and
wherein the first resistance layer further includes a second dopant that increases a resistivity of the resistance material.

11. The semiconductor device according to claim 10, wherein the resistance material has the resistivity higher than a resistivity of a material for forming the first conductive line or the second conductive line.

12. The semiconductor device according to claim 10, wherein the resistance material includes tungsten silicon nitride, and
wherein the second dopant includes one or both of silicon and nitrogen.

13. The semiconductor device according to claim 9, wherein the resistance layer has a line shape overlapping the first conductive line and disposed between the first conductive line and the corresponding memory cells.

14. The semiconductor device according to claim 9, wherein the resistance layer has a line shape overlapping the second conductive line and disposed between the second conductive line and the corresponding memory cells.

15. A semiconductor device comprising:
a substrate including a peripheral circuit region and a cell region having a first cell region and a second cell region, the second cell region being farther from the peripheral circuit region than the first cell region;
a plurality of first conductive lines disposed over the substrate and extending in a first direction;
a plurality of second conductive lines disposed over the first conductive lines and extending in a second direction that intersects the first direction;
a plurality of memory cells respectively disposed at intersection regions between the first conductive lines and the second conductive lines; and
a resistance layer disposed between the first conductive line and one or more of the memory cells corresponding to the first conductive line, or between the second conductive line and one or more of the memory cells corresponding to the second conductive line,
wherein the resistance layer includes a first resistance layer disposed in the first cell region and a second resistance layer disposed in the second cell region,
wherein the first resistance layer and the second resistance layer include a resistance material, and
wherein the first resistance layer further includes a dopant that increases a resistivity of the resistance material.

16. The semiconductor device according to claim 15, wherein the resistance material has the resistivity higher than a resistivity of a material for forming the first conductive line or the second conductive line.

17. The semiconductor device according to claim 16, wherein the resistance material includes tungsten silicon nitride, and
wherein the dopant includes one or both of silicon and nitrogen.

18. The semiconductor device according to claim 16, wherein the resistance layer has a line shape overlapping the first conductive line and disposed between the first conductive line and the corresponding memory cells.

19. The semiconductor device according to claim 16, wherein the resistance layer has a line shape overlapping the second conductive line and disposed between the second conductive line and the corresponding memory cells.

20. A method for fabricating a semiconductor device, comprising:
providing a substrate including a peripheral circuit region and a cell region having a first cell region and a second cell region, the second cell region being farther from the peripheral circuit region than the first cell region; and
forming a plurality of first conductive lines extending in a first direction, a plurality of second conductive lines extending in a second direction that intersects the first direction, and a plurality of memory cells disposed at intersections regions between the first conductive lines and the second conductive lines, respectively, over the substrate,
wherein the forming of the memory cells includes forming an electrode layer in each of the memory cells, and
wherein the forming of the electrode layer includes forming an electrode material layer, doping the electrode material layer in the first cell region with a first dopant for increasing a resistivity of the electrode material layer, and patterning the electrode material layer.

21. The method according to claim 20, wherein the electrode material layer includes amorphous carbon, and the first dopant includes nitrogen.

22. The method according to claim 20, wherein the electrode material layer includes nitrogen-added amorphous carbon, and the first dopant includes nitrogen.

23. The method according to claim 20, further comprising:
forming a resistance layer between the first conductive line and one or more of the memory cells corresponding to the first conductive line, or between the second conductive line and one or more of the memory cells corresponding to the second conductive line.

24. The method according to claim 23, wherein the forming of the resistance layer includes:
forming a resistance material layer; and
doping the resistance material layer in the first cell region with a second dopant that increases a resistivity of the resistance material layer.

25. The method according to claim 24, wherein the resistance material layer includes tungsten silicon nitride, and the second dopant includes one or both of silicon and nitrogen.

26. A method for fabricating a semiconductor device, comprising:
providing a substrate including a peripheral circuit region and a cell region having a first cell region and a second cell region, the second cell region being farther from the peripheral circuit region than the first cell region;
forming a plurality of first conductive lines extending in a first direction, a plurality of second conductive lines extending in a second direction intersecting the first direction, and a plurality of memory cells disposed at intersections regions between the first conductive lines and the second conductive lines, respectively, over the substrate; and
forming a resistance layer between the first conductive line and one or more of the memory cells corresponding to the first conductive line, or between the second conductive line and one or more of the memory cells corresponding to the second conductive line,
wherein the forming of the resistance layer includes:
forming a resistance material layer; and
doping the resistance material layer in the first cell region with a dopant that increases a resistivity of the resistance material layer.

27. The method according to claim 26, wherein the resistance material layer includes tungsten silicon nitride, and the dopant includes one or both of silicon and nitrogen.
